(19) United States
(12) Patent Application Publication
(10) Pub. No.: US 2009/0003484 A1
(43) Pub. Date: Jan. 1, 2009

(54) DEVICE AND METHOD FOR COMMUNICATION USING HYBRID MODULATION

(76) Inventors: Wei Li, Daly City, CA (US); John Benko, San Francisco, CA (US)

Correspondence Address: THORNE & HALAJIAN;APPLIED TECHNOLOGY CENTER, 111 WEST MAIN STREET, BAY SHORE, NY, 11706, US

(21) Appl. No.: 11/771,977

(22) Filed: Jun. 29, 2007

(51) Int. Cl. H03K 7/06

(52) U.S. Cl. 375/271

(57) ABSTRACT

A method and system for modulating a signal includes providing a carrier including periodic waves, peaks of the periodic waves defining a carrier shape of the carrier; changing a plurality of the periodic waves so that peaks of the changed waves form a shaped signal having a signal shape which is different from the carrier shape; and detecting the shaped signal.

### FIELD OF THE PRESENT SYSTEM

The present system relates to a method, system and device for communication using hybrid modulation schemes.

### BACKGROUND OF THE PRESENT SYSTEM

The quest for more efficient and reliable communication continues with the increase in information exchanges, due to widespread wired and wireless communication and Internet use. Data exchange continues to increase including audio/video or other content, e.g., music, television programming, Voice over the Internet VoIP telephony, and the like, through networks such as the Internet.

The explosion of information exchange demands increased use of the frequency spectrum. Various communication and compression methods are known that make efficient use of available resources including the frequency spectrum. Content delivery requirements vary based on content size, security and reliability. Large-sized content such as video requires a large bandwidth for reliable and/or fast communication, where compression is often used to reduce bandwidth requirements.

Information or any content, also referred to as useful data information or message, is transmitted using a carrier signal 10 shown in FIG. 1A in the time-domain (where the x-axis is in units of time (t) such as seconds). The carrier signal 10 is a periodic wave or repeated cycles or waves 20, each having the same frequency f₀, or period T where f₀=1/T.

In the frequency spectrum or domain shown in FIG. 1B (where the x-axis is in units of frequency (f) such as Hz), the carrier signal 10 is a single line 30 at a single frequency f₀. A message or useful data is typically modulated on the carrier signal 10 by changing the carrier signal using different types of modulation, such as amplitude modulation (AM), frequency modulation (FM), phase modulation, pulse position modulation (PPM).

FIG. 1C shows a modulated carrier 40 in the frequency domain, where data is included in sidebands 50 of the carrier frequency 30′. To prevent interference between adjacent channels having different carrier frequencies, certain bandwidth is dedicated to the modulated carrier signal. Reducing sidebands allows reduction in bandwidth thus increasing efficiency and utilization of the frequency spectrum, where channels can be spaced closer to each other.

To reduce sidebands, data is transmitted by minimally changing the carrier signal. For example, U.S. Pat. Nos. 7,023,932 and 6,968,014 both to Bobier, which are incorporated herein by reference in their entirety, describe changing a single cycle or wave of the carrier signal. In particular, the frequency, amplitude or phase of a single wave is changed, or a single wave is deleted from the carrier signal. Since only a single wave is changed, the carrier sidebands are at minimal levels.

A receiver detects the deletion of, or change in, the single wave of the carrier signal, where the position of the deleted or changed waves conveys useful data. As is well known, modulation where position is used to convey useful data is referred to as pulse position modulation or PPM.

Such conventional transmission and modulation methods, where a single wave is deleted or changed, allow for closer spacing of different carrier frequencies and thus efficient use of the frequency spectrum, since the required bandwidth is minimized due to reduced sidebands. However, detection of deletion or changes of a single wave requires a sensitive and costly receiver. Further, errors are introduced in the case where the single deleted or changed wave is not detected.

Accordingly, there is a need for improved communication and modulation schemes which are more robust, simpler and more cost efficient.

### SUMMARY OF THE PRESENT SYSTEM

It is an object of the present system and method to overcome disadvantages and/or make improvements in the prior art.

The present system, method and device for modulating a signal include providing a carrier having periodic waves, peaks of the periodic waves defining a carrier shape of the carrier; changing a plurality of the periodic waves so that peaks of the changed waves form a shaped signal having a signal shape which is different from the carrier shape; and detecting the shaped signal.

Further areas of applicability of the present systems and methods will become apparent from the detailed description provided hereinafter. It should be understood that the detailed description and specific examples, while indicating exemplary embodiments of the systems and methods, are intended for purposes of illustration only and are not intended to limit the scope of the invention.

### BRIEF DESCRIPTION OF THE DRAWINGS

These and other features, aspects, and advantages of the device, apparatus, systems and methods of the present invention will become better understood from the appended claims, and by way of example, from the following description with reference to the accompanying drawings where:

FIGS. 1A-1C show waveforms of a carrier signal with and without modulation;

FIG. 2 shows a system in accordance with an embodiment of the present system;

FIGS. 3A-3B show a PPM scheme in accordance with an embodiment of the present system; and

FIGS. 4A-4B and 5A-5B show time-domain and frequency domain representations of modulated signals with various shaped pulses in accordance with different embodiments of the present system.

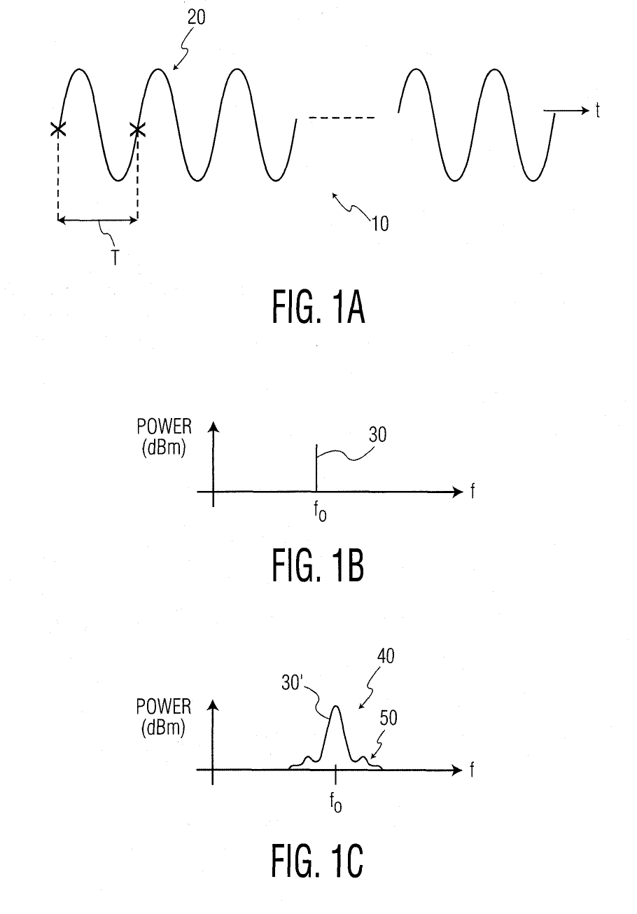

### DETAILED DESCRIPTION OF THE PRESENT SYSTEM

The following are descriptions of illustrative embodiments that, when taken in conjunction with the drawings, will demonstrate the above noted features and advantages, as well as further ones. In the following description, for purposes of explanation rather than limitation, illustrative details are set forth such as architecture, interfaces, techniques, element attributes, etc. However, it will be apparent to those of ordinary skill in the art that other embodiments that depart from these details would still be understood to be within the scope of the appended claims. Moreover, for the purpose of clarity, detailed descriptions of well known devices, circuits, modulation techniques and methods are omitted so as not to obscure the description of the present system. It should be expressly understood that the drawings are included for illustrative purposes and do not represent the scope of the present system.

The following detailed description is therefore not to be taken in a limiting sense, and the scope of the present system is defined only by the appended claims. The leading digit(s) of the reference numbers in the figures herein typically correspond to the figure number, with the exception that identical components which appear in multiple figures are identified by the same reference numbers.

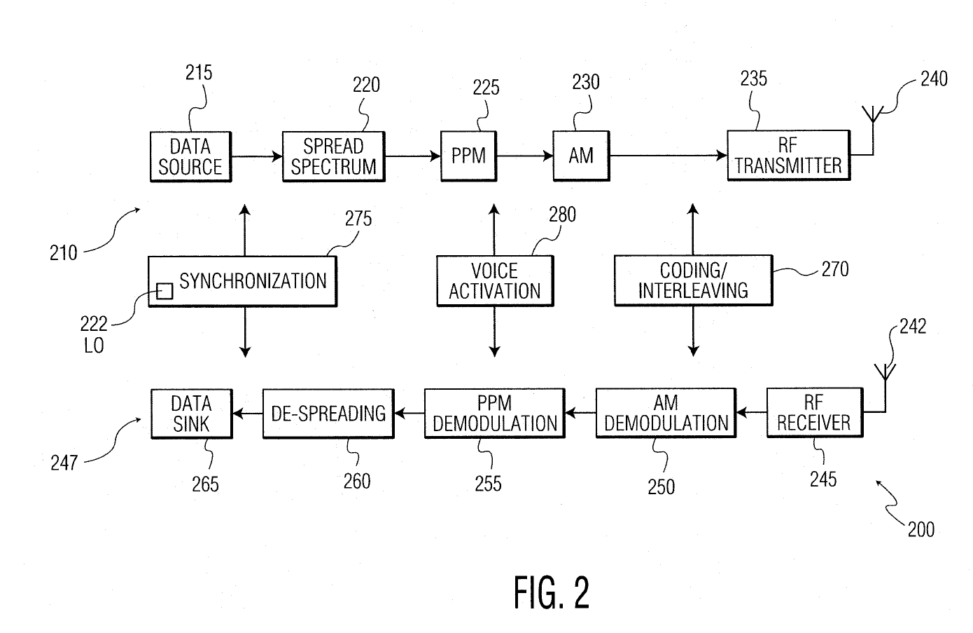

FIG. 2 shows a system 200 in accordance with an embodiment of the present system. The system 200 is based on Spread Spectrum-Amplitude Modulation including multiple-position Bipolar Pulse Position Modulation (BPPM), e.g., N-ary BPPM.

As shown in FIG. 2, instead of traditional Amplitude modulation (AM) or Pulse Position modulation (PPM), a hybrid modulation scheme is provided that includes both PPM and AM, which may also employ spread spectrum. Such a hybrid modulation scheme is well suited for relatively low data rates, such as used in VoIP, for example, where non-coherent demodulation and DSP based signal detection may be used to reduce complexity and cost. An impulse shaped pulse or square/rectangular pulse, and/or any other shape or combination of different shaped-pulses may be used. That is, pulses (associated with useful data or message) may be used that have different choices of optimal shapes according to different channels, systems and requirements. Differential modulation may also be used where previous signal characteristics are taken into account for modulating a current signal (occurring after the previous signal).

For VoIP systems, for example, considering the actual carrier frequency may not be higher than 600 MHz, a lower sampling rate may be used. Further, since an AM-like technology is used, the spread spectrum scheme may include frequency hopping, time hopping and/or direct sequence spread where a message unit is provided in the same slot or multiple frames or sequences, e.g., in slot 5 of sequences or frames 1 and 20 for example. An N-ary BPPM has time hopping by itself when N>2 thus providing an extra diversity gain while combined with spread spectrum schemes.

As shown in FIG. 2, the system 200 includes a transmitter 210 for transmitting data provided by a data source 215. The data and source 215 may be any type of data and source, such as audio and/or video content provided by a broadcaster or a user, where a user may generate data from a terminal, such as a computer, telephone, personal digital assistant (PDA) and the like. The data to be transmitted, which may be any type of data, may include voice in the case of a telephone system, whether wired, wireless, mobile, cellular, VoIP etc.

Information, content or any useful data or message from the data source 215 is provided to an optional spread spectrum module 220 for spreading the content over a wide band, such as over a wide frequency or time band. Spreading, e.g., in the frequency domain (and/or the time domain) provides more secure communication as well as increased resistance to interference and jamming. The spread spectrum module 220 may use any of the well-known spreading schemes, such as direct sequence spread spectrum (DSSS), frequency hopping spread spectrum (FHSS), chirp spread spectrum (CSS), or a hybrid/combination of the various spreading schemes. Further, multiple access and/or multiple function schemes may also be used for sharing resources, such as frequency and/or time slots, for example, using frequency division multiple access (FDMA) and/or time division multiple access (TDMA). As is well known, a receiver de-spreads and correlates the received spread signal to reconstruct or retrieve the original useful data, content, message or information signal.

The spread output of the spread spectrum module 220 is provided to a Pulse Position modulation (PPM) unit 225 for modulating a carrier signal in accordance with the useful data or message. The carrier signal may be provided by a local oscillator (LO) 222 which may be fixed or variable such a voltage controlled oscillator (VCO), for example. Illustratively, the LO 222 is provided in a synchronization unit 275. As is well known, an N-ary PPM encodes a message having k bits (where N=2^{k}) by providing a single pulse at one particular location of one of 2^{k} possible time-shifts or time slots forming a frame or a symbol.

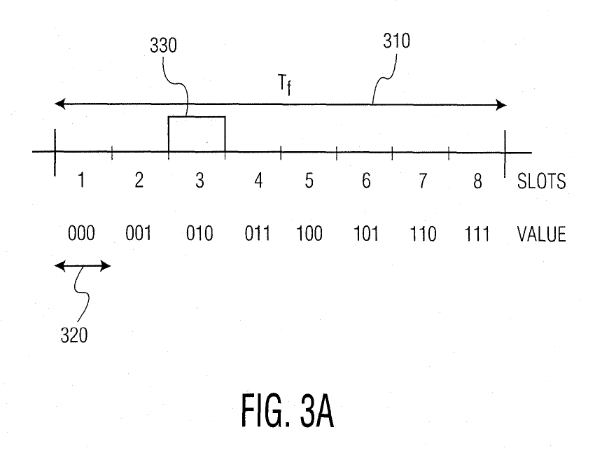

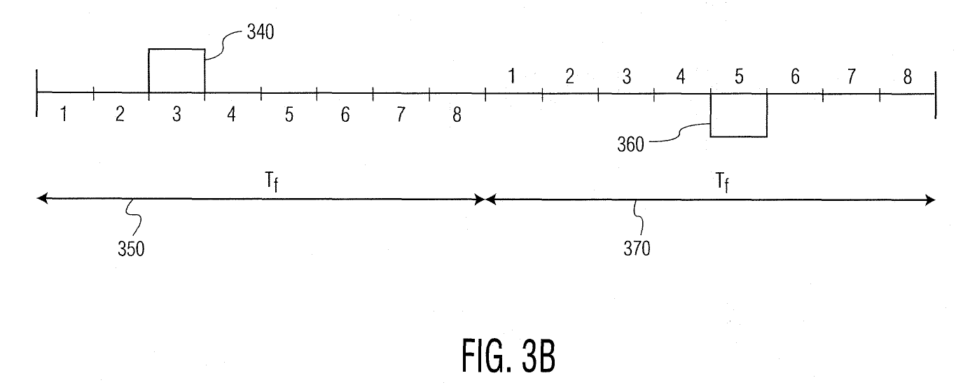

FIG. 3A shows a PPM scheme for encoding a binary message of 3 bits (k=3). As shown in FIG. 3A, a frame or symbol 310 of a 3-bit message x₁x₂x₃ is divided into N equal-size time slots, where the number of slots N is 8, namely, N=2^{k}=2³=8 slots 320, where each slot 320 of the eight slots is associated with one of the 8 possible values of the 3 bit message. For example, messages or message values of 000, 001, 010, 011, 100, 101, 110 and 111 are associated with slots 1 through 8, respectively. This is repeated every T_{f} seconds, such that the transmitted bit rate is k/T_{f} bits per second. In FIG. 3A, a binary message of 010 is encoded by providing a pulse 330 in the third slot. Upon reception of the frame 310, a synchronized receiver determines that the pulse 330 is in the third position of the frame 310 and thus decodes the message as 010, which is the value associated with the third position of the frame 310.

For Bipolar Pulse Position modulation (BPPM), where two orthogonal periodic carriers are used, an additional bit may also be provided to indicate the sign or polarity of the message. Thus, for BPPM, the number of slots N in a frame or symbol 310 is 2^{k} for a (k+1)-bit message. The additional sign or polarity slot may be the least, the most significant bit, or any other desired bit for example. FIG. 3B shows a BPPM modulated signal including a positive pulse 340 at the third slot of a first frame 350, and a negative pulse 360 at the fifth slot of a second frame 370. Thus, by taking into account the sign or phase of the pulses 340, 360, an additional bit of information (which may be the least or most significant bit, for example,) may be included in a frame of the same period or frame time T_{f} as the PPM modulation scheme shown in FIG. 3A.

In particular, a set of N=2^{k+1} BPPM signals include the antipodal version of the orthogonal PPM signals. An N-ary BPPM signal Sₘₙ is defined as an N/2-dimensional vector with nonzero value in the nth dimension as shown in equation (1):

Sₘₙ=[0, . . . 0,Aₘ\sqrt{E_{g}},0, . . . 0], (1)

where N is an even integer, and N>0, 1≦n≦N/2, m=1 or 2, A₁=1, A₂=−1, and E is the average energy of the signal.

A typical time hopping impulse format for the signal is given by the equation (2):

$$s ( t ) = {\sum }_{j = - ∞}^{∞} Aq ( t - {jT}_{f} - ϕ ) cos ( ω t - {jT}_{f} - ϕ ) , \qquad ( 2 )$$

where q(t) represents the transmitted impulse waveform that nominally begins at time zero. T_{f} is the frame time, also shown in FIGS. 3A-3B, which is typically a hundred to a thousand times the impulse width (which may be up to the width of a slot 320) resulting in a signal with very low duty cycle.

Returning to FIG. 2, the PPM (or BPPM) unit 225 encodes the message or useful data spread by the spreader 220 by providing a pulse of a particular shape at the particular location or slot of a frame associated with the message. The output of the PPM (or BPPM) 225 is provided to an Amplitude modulation (AM) unit 230 which amplitude modulates the PPM (or BPPM) encoded signal. The output of the AM unit 230 is provided to a transmitter 235 that includes a power amplifier for example, as is well known, for amplification and transmission of the modulated signal carrying the message, e.g., via an antenna 240 over the air.

Although the illustrative embodiment shown in FIG. 2 uses amplitude modulation, it should be understood that a pulse of a desired shape may be implemented or provided by any type of carrier modulation, such as amplitude, frequency, and/or phase modulation in combination with any type of pulse modulation such as PPM, BPPM and the like. However, the combination of amplitude/impulse/PPM (differential) modulation of carriers may be readily and practically implemented at reasonable or reduced cost, where a simpler receiver may be used to detect the shaped pulse, such as an impulse-shaped pulse using an envelope detector and/or a matched filter, for example.

As shown in FIG. 2, a receiver unit 247 receives the modulated signal transmitted by the transmitter 235 of the transmitter unit 210. The receiver unit 247 performs inverse operations of the transmitter unit 210 to extract the message or useful data from received the modulated signal.

In particular, the modulated signal transmitted from transmitter 235 via the transmitting antenna 240 is received by a receiver 245, e.g., via a receiving antenna 242 over the air. As is well known, the receiver 245 may have various filters, tuners, and/or low noise amplifiers to detect the modulated signal and process it, such as filtering, downconverting, etc. For example, the receiver 245 may include a filter having characteristics matched to the modulated signal, e.g., configured to detect an impulse shaped pulse, or a square/rectangular shaped pulse, or any other shape that may be included in the modulated signal as known, e.g., a priori, by the receiver unit 247. One or more matched filters, having fixed or dynamically adjustable characteristics may be provided for changing the characteristics of the filter to match the expected characteristics e.g., pulse shape, included in the modulated signal being detected.

As is well known, the received signal may be passed through a channel or bandpass filter and down-converted from a typically high RF frequency, to a lower frequency via mixers, for example. The filtered and/or downconverted signal is provided from the receiver 245 to an AM demodulator 250 for demodulating, e.g., envelope detecting and/or match filtering the downconverted signal. If desired, to demodulate the downconverted signals, the filter and envelope detector may be reversed in the sense that the received signal is first filtered followed by an envelope detector.

As shown in FIG. 2, the AM demodulated signal is provided to a PPM demodulator 255 for demodulating and extracting the position or location of the received pulse within the slots of a frame or symbol. As described in relation to PPM and FIGS. 3A-3B, the pulse location is associated with the message or useful data.

In the case where the modulated signal was spread by the optional spread spectrum module 220 of the transmitter unit 210, then a de-spreading module 260 is provided in the receiver unit 247. Illustratively, the de-spreading module 260 receives the output of the PPM demodulator 255 and de-spreading the AM and PPM demodulated signal, thus recovering the message or useful data included in the modulated signal transmitted by the transmitter unit 210. Finally, the recovered message is rendered or provided to a rendering device or data sink 265, such as an output device, e.g., display, speaker etc. Alternatively or in addition, the recovered message is provided to a processor for further processing, and/or to a memory for storage. It should be understood that the described embodiments are merely illustrative and one skilled in the art can envision multiple ways of implementing various aspects thereof, where other embodiments would still be within the scope of the appended claims.

As is well known, various schemes may be performed for additional security and/or efficiency. For example, the signal transmitted by the transmitter may be further encoded, encrypted and/or compressed. Further, other signals may be communicated between the transmitter and receiver to facilitate detection of the transmitted modulated signal and recovery of the message. Such additional signals may be communicated with the modulated signal using the same channel or using different channels or sub-channels.

For example, encryption keys or key identifiers may also be transmitted by the transmitter unit 210 to facilitate decryption. Accordingly, an encryption, coding and/or interleaving device may be provided in the transmitter unit 210, with an inverse device provided in the receiver unit 247, such as a de-encryption device to perform inverse operations of complementary devices in the transmitter and/or complementary operation performed by the transmitter. Such complementary devices in the transmitter 210 and receiver 247 units may be included in the system in 200. A channel coding and interleaver unit may also be utilized to further improve performance of the system, such as to provide channel diversity, as shown by reference numeral 270 in FIG. 2.

Synchronization signals may also be transmitted to synchronize the receiver unit 247 to the transmitter unit 210. Illustratively, the synchronization (sync) signal provides a reference indicating the start of a frame or symbol. Thereafter, the receiver may count its local clock from its local oscillator, for example, to determine the position of a pulse in relation to the sync signal or the start of a frame. A synchronization device included in the transmitter 210 and receiver 247 units is shown as reference numeral 275 in FIG. 2.

Having prior knowledge of the frame size and number of slots in a the frame, a sync or reference signal transmitted from the transmitter indicating the beginning of a frame may be all that is needed by the receiver to correctly determine the location of the received shaped-pulse and thus correctly extract the message or useful data. Of course, a sync signal may be transmitted periodically by the transmitter or upon request by the receiver to resynchronize as necessary, including transmitting the sync signal with each frame if desired.

Since the shaped pulse includes multiple waves and information is associated with the position of the shaped pulse instead of its amplitude, a relatively simple receiver may be used for detecting the shaped pulse and its position. Even if certain waves of the shaped pulse are not detected, or the receiver is not fully synchronized with the receiver and the shaped pulse overlaps two slots of the frame, detecting a majority of waves of the shaped pulse within a particular slot may be indicative that the shaped pulse belongs in the particular slot or location of the frame where the majority of the waves are detected. It should be understood that synchronization may be provided by other means or methods that is apparent to ones skilled in the art in view of the present system.

Further devices may be provided in the transmitter 210 and/or receiver 247 units, such as a voice activation device 280 to increase capacity of the transmitter 210 and/or receiver 247 units and improve overall performance. Illustratively, the voice activation device 280 turns off the devices, such as the transmitter 210 and/or the receiver 247 or parts thereof, during quiet or dead time. For example, the voice activation device 280 may turn on/off all or parts of the transmitter 210 and/or the receiver 247, e.g., fifteen to twenty times per second, thus increasing battery life of mobile device including the transmitter 210 and/or the receiver 247, reducing interference or noise (since the transmitter is turned off) and/or increasing capacity.

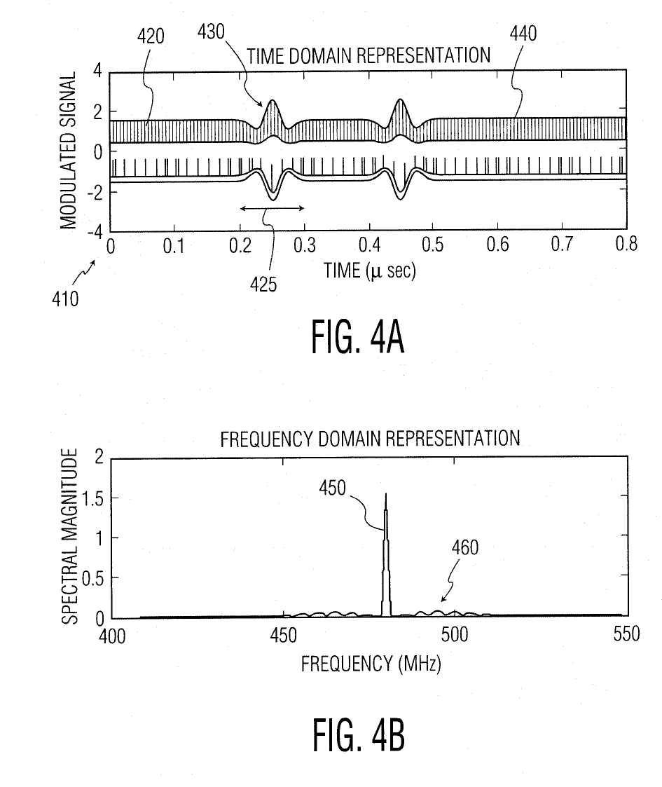

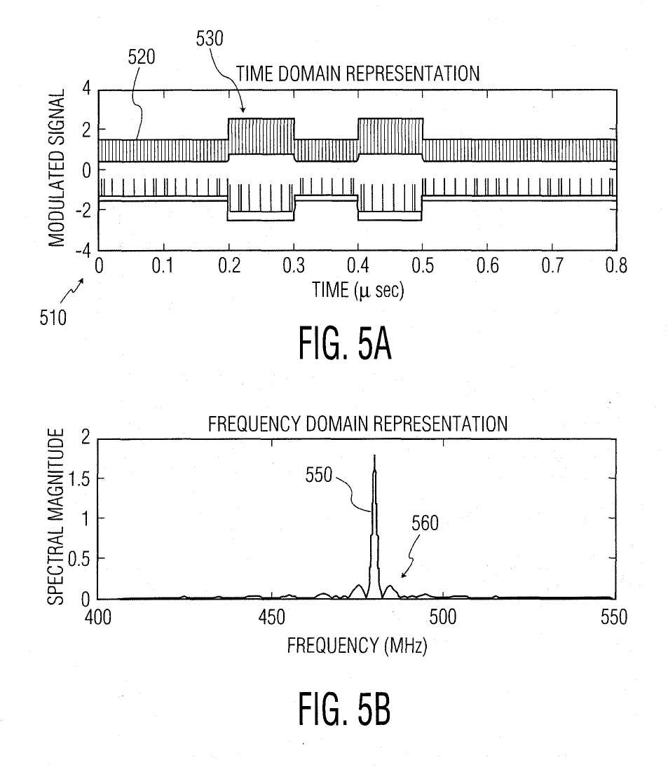

FIGS. 4A-4B and 5A-5B show simulation results for one of the many possible implementations of the system 200 shown in FIG. 2, where the frequency of the carrier signal 420, 520 is 480 MHz, and the data is spread over a 100 MHz frequency band with a spreading ratio 31. FIGS. 4A-4B show impulse signals for PPM (Pulse Position Modulation), and FIGS. 5A-5B show rectangular signals used for PPM.

For this illustrative example, the energy ratio of the pilot frequency (i.e. carrier at 480 MHz) and the signals is 1.52. BPPM and AM modulations are performed, where N=8 with PPM pulse duration or width 425, 525 of 0.1 μs, and sampling rate 1.2 GHz. There is little or no theoretical difference between these two signal shapes 430, 530 shown in FIGS. 4A and 5A. However in practical systems, impulse signals 430 are more popular for they are easy to generate.

In FIGS. 4A-4B and 5A-5B, the spectral magnitude and modulation amplitude are relative. However, if the signal power is limited the same with the background noise, with the 100 MHz bandwidth, the system capacity may be estimated to be about 60 Mbit/s as shown by equation (3):

C=Blog₂(1+S/N)≈10⁸ log₂(1+½)≈60 Mbit/s (3)

which is the theoretical capacity limit of such a system. Typically, the capacity of practical systems are approximately between 20 Mbit/s˜30 Mbit/s, depending on the modulation schemes and channel condition.

In particular, FIGS. 4A and 4B show time-domain and frequency domain representations of a modulated signal 410, showing two successive frames or symbols each having a pulse at a particular location of the frame or symbol associated with the useful data or message. The modulated signal 410 is transmitted by the transmitter 240 and received by a receiver 245 of a receiver unit 247, e.g., via a receiving antenna 242 shown in FIG. 2. As shown in FIG. 4A, modulated signal 410 includes the carrier signal 420 provided from the LO 222, for example, to the PPM (or BPPM) unit 225, which provide a particular shape pulse in a particular slot of the symbol or frame 310, as described in connection with FIGS. 3A-3B.

In FIG. 4A, the shape of the pulse 430 is an impulse or (sinX)/X, where two impulses are shown in successive frames or symbols. The AM unit 230 amplitude modulates the carrier 420 where the peaks of the carrier define an envelope 440 of the modulated signal 410. Portions of the modulated signal not including the impulse include the carrier signal itself with periodic waves or cycles of positive and negative amplitudes, for example.

As shown in the frequency domain of the modulated signal, shown in FIG. 4B, most of the energy is primarily at the carrier frequency 450, with sideband 460 that include the message or useful data at a considerably lower magnitude than the magnitude the carrier frequency 450. That is, efficient utilization of the frequency spectrum is maintained, thus allowing for close spacing of various channels of different carrier frequencies. Further, security and robustness are enhanced. In addition, non-coherent demodulation and digital signal processor (DSP) based signal detection may be used, thus reducing receiver complexity and cost. A matched filter may also be used in the receiver unit 252, matched to the shape of the pulse, in this case, a filter matched to an impulse shape to detect and filter the impulse 430.

FIGS. 5A and 5B shows time-domain and frequency domain representations of a modulated signal 510, similar to FIGS. 4A and 4B except that, instead of the shape of pulses (associated with the message) being impulses [(sinX)/X], rectangular-shaped pulses 530 are generated from the PPM and AM modulation combination. As shown in FIG. 5B, the carrier frequency 550 includes sidebands 560 which have a larger amplitude than the sidebands 460 of the impulse shaped pulse shown in FIGS. 4A-4B.

The present systems and methods outperform many RF systems currently available in both wireless and wired world for various communication services, such as Internet telephony or communication using Voice over Internet Protocol (VoIP), for example.

Of course any type of communication means may be used, such as via different types of channels, wired or wireless, using radio frequency (RF), infrared (IR), sonar, optical signals and/or packets and the like. Further, the transmitter and receiver units may have various elements to facilitate communication, such as multiplexer, analog to digital (A/D) and/or digital to analog (D/A) converters, mixers, up and/or down converters, filters, duplexers, processors, controllers, memory, and the like.

The methods of the present system are particularly suited to be carried out by a computer software program, to control transceivers for example, such program containing modules corresponding to one or more of the individual steps or acts described and/or envisioned by the present system. Such program and elements thereof may of course be embodied in a computer-readable medium, such as an integrated chip, a peripheral device or memory, and/or other one or more memories coupled to the one or more processors.

One or more of the mediums may be any recordable device (e.g., RAM, ROM, removable memory, CD-ROM, hard drives, DVD, floppy disks or memory cards) or may be a transmission medium (e.g., a network comprising fiber-optics, the world-wide web, cables, a wireless channel using time-division multiple access, code-division multiple access, other radio-frequency and/or wireless communication channel). Any medium known or developed that may store and/or transmit information suitable for use with a computer system, processor, etc., may be used as one or more of the mediums.

These memories may configure the processor to transmit and receive signals and implement the methods, operational acts, and functions disclosed herein. The memories may be distributed or local and the processor, where additional processors may be provided, may also be distributed or may be singular. The memories may be implemented as electrical, magnetic or optical memory, or any combination of these or other types of storage devices. Moreover, the term “memory” should be construed broadly enough to encompass any information able to be read from or written to an address in the addressable space accessible by a processor. With this definition, information on a network is still within the memory, for instance, because the processor may retrieve the information from the network for operation in accordance with the present system.

The one or more processors may be capable of providing control signals and/or performing operations in response to input signals from a user input device, such as provided via a keyboard of a voice recognition module, and executing instructions stored in the one or more memories. One or more of the processors may be an application-specific and/or general-use integrated circuit(s). Further, the processors may be a dedicated processor for performing in accordance with the present system and/or may be a general-purpose processors, including digital signal processors (DSPs) wherein only one of many functions operates for performing in accordance with the present system. The one or more processors may operate utilizing a program portion, multiple program segments, and/or may be a hardware device utilizing a dedicated or multi-purpose integrated circuit. Further, in a distributed system, portions of an operation may be performed on one device with data generated therefrom being transferred to one or more further devices.

The present system/device/method provides numerous benefits of prior systems. For example, through use of the present system/device/method in accordance with an embodiment, ease of detection of the shaped-pulses is provided, since the energy within the pulse and/or shape thereof, including pulse width and amplitude, may be varied based on system requirement and channel conditions. Thus, when channel conditions deteriorate and excessive noise or interference is present, energy of the shaped-pulse may be increased in response to detection of noisy conditions or when increased reception errors are detected.

A further advantage of a pulse that includes many cycles or waves, in addition to being able to provide a desired pulse shape, is the ease of detection or reception by a tuned receiver as compared with detecting or receiving a single wave, since more energy is present in the shaped pulse of many waves. Further, if the single is not detected, then data is missed resulting in an undetected message or detection of an erroneous message. By contrast, if one or few of the waves that form the pulse are not detected, there is still a high likelihood of detection of other waves that form the shaped pulse, resulting in proper reception/detection of the shaped pulse. If necessary, the undetected waves may be estimated or interpolated, which is likely not to be needed since with the use of PPM, the presence or location of the shaped pulse conveys the message or the useful data, and not the actual shape, amplitude, frequency or duration of the pulse.

Further, the receiver may include a filter matched to the shape of the shape to better detect and filter the shaped pulse in the transmitted signal. The receiver is relatively simple and thus inexpensive, where an envelope detector may be used to detect the envelope of the modulated signal and extract the shaped-pulse, whose location within a frame provides useful data or message, or part thereof. Thus, the particular parameters that make up the shaped pulse, such as, amplitude, width, frequency, are not critical as such parameters do not convey any information, which is associated with the location of the pulse.

The receiver detection threshold may be designed as needed, which may be a low threshold where detection of one or more of the plurality of the waves that form the pulse may be enough to estimate or determine with reasonable likelihood or probability that a pulse of the expected shape is present in a particular slot of a frame, so long as some aspects, e.g., amplitude of the detected wave(s) match a portion of the expected shape of the pulse.

In the case where one pulse is present in one of the slots of frame, the rest of the frame is not used, which may be inefficient from a bandwidth utilization point of view, but robustness against noise or interference, for example, is increased. Such a scheme reduces sidebands and increases energy of the fundamental frequency which increases robustness and immunity to noise, thus providing for simpler detection and less complex or sensitive receivers. The sidebands may be reduced below the noise floor thus preventing interference with other signals, and easily complying with regulatory agencies such as the U.S. Federal Communication Commission (FCC). Looking for and detecting a particular shaped pulse, e.g., via a matched filter allows for detection of such pulses even when they are below the noise floor.

Of course, one skilled in the art in view of the present system may ascertain many variations where, for example, frequency and/or time sharing may be provided. Illustratively, a random sequence known to both the transmitter and receiver may be used for frequency and/or time hopping and/or sharing, thus increasing efficiency as well as robustness, immunity to noise, and security. Each slot may also be shared, where pulses of different shape, frequency, phase, and/or amplitude, may fully or partially occupy the same slot.

For example, an impulse may be present in the first half of a slot, where a square/rectangular pulse may be present in the second half, of the same or different frequency, phase, and/or amplitude. A receiver with matched filters matching the impulse and/or square/rectangular shaped pulses may detect and discern two message units from one slot, one message unit of a first message from the impulse shaped-pulse and another message unit of a second message from the square/rectangular shaped-pulse.

As is well known, a reference or synchronization signal may be transmitted from the transmitter to the receiver for synchronizing the receiver, such as to ascertain the beginning of a frame. Once the receiver is synchronized, such as after determining the beginning of a frame, waves of a known frequency, such as a local clock signal provided from a local oscillator, may be counted to ascertain slot locations in a frame, or the beginning of further frames and the like, based on prior knowledge of a frame size and the number of slots per frames, for example.

It should be noted that the transmitted message does not decay to zero, and energy is maintained thus maintaining synchronization. Accordingly, the receiver need only be synchronized with the transmitter once, after which synchronization is maintained, without further synchronization signals, such as by counting waves of the carrier and/or a local clock of the receiver.

Of course, it is to be appreciated that any one of the above embodiments or processes may be combined with one or more other embodiments and/or processes or be separated and/or performed amongst separate devices or device portions in accordance with the present system.

Finally, the above-discussion is intended to be merely illustrative of the present system and should not be construed as limiting the appended claims to any particular embodiment or group of embodiments. Thus, while the present system has been described with reference to exemplary embodiments, it should also be appreciated that numerous modifications and alternative embodiments may be devised by those having ordinary skill in the art without departing from the broader and intended spirit and scope of the present system as set forth in the claims that follow. In addition, the section headings included herein are intended to facilitate a review but are not intended to limit the scope of the present system. Accordingly, the specification and drawings are to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function;

e) any of the disclosed elements may be comprised of hardware portions (e.g., including discrete and integrated electronic circuitry), software portions (e.g., computer programming), and any combination thereof;

f) hardware portions may be comprised of one or both of analog and digital portions;

g) any of the disclosed devices or portions thereof may be combined together or separated into further portions unless specifically stated otherwise;

h) no specific sequence of acts or steps is intended to be required unless specifically indicated; and

i) the term “plurality of” an element includes two or more of the claimed element, and does not imply any particular range of number of elements; that is, a plurality of elements may be as few as two elements, and may include an immeasurable number of elements.

What is claimed is:

1. A method of modulating a signal comprising the acts of:
providing a carrier including periodic waves, peaks of the periodic waves defining a carrier shape of the carrier;
changing a plurality of the periodic waves so that peaks of the changed waves form a shaped signal having a signal shape which is different from the carrier shape; and
detecting the shaped signal.

2. The method of claim 1, wherein a position of the shaped signal provides useful data.

3. The method of claim 1, further comprising the act of dividing the carrier signal into portions, each of the portions defining a frame, wherein a location of the shaped signal within the frame conveys useful data.

4. The method of claim 1, wherein the changing act includes pulse position modulating and amplitude modulating an input signal having a message to form a transmit signal, and wherein the detecting act detects the shaped pulse from the transmit signal.

5. The method of claim 1, wherein the changing act includes pulse position modulating an input signal having a message to form a first modulated signal and amplitude modulating the first modulated signal to form a transmit signal, and wherein the detecting act detects the shaped pulse from the transmit signal.

6. The method of claim 1, wherein the detecting act is performed by a matched filter which is configured to filter the shaped signal and has filter characteristics matching the shaped signal.

7. The method of claim 6, further comprising the act of providing a filtered output of the matched filter to an envelope detector configured to demodulate the filtered output and extract the shaped signal.

8. The method of claim 1, wherein the detecting act is performed by a matched filter configured to detect the shaped signal from an output of an envelope detector which is configured to detect an envelope of the shaped signal.

9. The method of claim 1, wherein the shaped signal consists of a first portion having an amplitude which is greater than a maximum carrier amplitude of the carrier, and a second portion having an amplitude which is less than a minimum carrier amplitude, the first portion and the second portion being symmetric about the carrier.

10. The method of claim 1, wherein the shaped signal includes a first portion having an amplitude greater than a maximum carrier amplitude of the carrier and a second portion having an amplitude less than a minimum carrier amplitude, the first portion and the second portion being symmetric about the carrier.

11. The method of claim 1, further comprising the acts of:
spreading the shaped signal to form a spread signal;
transmitting the spread signal;
receiving the spread signal; and
de-spreading the received spread signal.

12. A system for communication comprising:
a transmitter device configured to change a plurality of periodic waves of a carrier signal to form a shaped signal having a signal shape which is different from a carrier shape of the carrier; and
a receiver device configured to detect the shaped signal.

13. The system of claim 12, further comprising:
a pulse position modulator configured to modulate an input signal having a message to form a pulse position modulated signal;
an amplitude modulator configured to modulate the pulse position modulated signal to form a transmit signal;
at least one of an envelope detector configured to detect an envelope of the transmit signal and a matched filter configured to filter the shaped signal, the matched filter having filter characteristics matching the shaped signal configured to detect the shaped signal from the transmit signal;
an amplitude demodulator configured to demodulate the detect the shaped signal to form a demodulated signal; and
a pulse position demodulator configured to demodulate demodulated signal and extract a message from a position shaped signal in the transmit signal.

14. The system of claim 12, further comprising:
a spreader configured to spread the shaped signal for transmission of a spread signal including the spread shaped signal; and
a spreader configured to receive the transmitted spread signal and to de-spread the received spread signal.

15. An information signal embedded in a carrier of periodic waves, the information signal having a signal shape which is different from a carrier shape of the carrier, a location of the signal shape being associated with a message, the signal shape being formed by pulse position modulating the carrier to form a pulse modulated signal and amplitude modulating the pulse modulated signal to form a transmit signal for transmission, wherein the signal shape is configured to match a filter configured to receive and filter the transmit signal for detecting the signal shape from the transmit signal.

16. The information of claim 15, wherein the shaped signal consists of a first portion having an amplitude which is greater than a maximum carrier amplitude of the carrier and a second portion which is less than a minimum carrier amplitude.
